(19) United States
(12) Patent Application Publication
(10) Pub. No.: US 2025/0102385 A1
(43) Pub. Date: Mar. 27, 2025

(54) MICROMECHANICAL PRESSURE SENSOR, METHOD FOR PRODUCING SAME, AND METHOD FOR DETECTING A PRESSURE VARIABLE

(71) Applicant: Robert Bosch GmbH, Stuttgart (DE)

(72) Inventors: Ferenc Lukacs, Budapest (HU); Volkmar Senz, Metzingen (DE)

(21) Appl. No.: 18/832,314

(22) PCT Filed: Feb. 8, 2023
(86) PCT No.: PCT/EP2023/053102

§ 371 Date: Jul. 23, 2024

(30) Foreign Application Priority Data
Feb. 16, 2022 (DE) 10 2022 201 590.8

(51) Int. Cl. G01L 9/00

(52) U.S. Cl. CPC G01L 9/0072

(57) ABSTRACT

A pressure sensor. The pressure sensor has a diaphragm that stretches over a cavity. A first electrode is provided in or on the diaphragm in a central region. A second electrode is provided on the cavity base so as to lie opposite the central region of the diaphragm or the first electrode. The second electrode is arranged in a fixed and rigid manner. The first electrode in or on the diaphragm is designed so as to be able to be flexibly deflected together with the diaphragm and move toward the second electrode when a pressure is applied to the diaphragm. Together, the first and second diaphragm form a first measuring capacitor, using which a pressure can be detected up to a pressure threshold. A second measuring capacitor is provided in the lateral region of the diaphragm.

### FIELD

The present invention relates to a micromechanical capacitive pressure sensor, to a corresponding micromechanical method for producing same, and to a method for detecting or deriving a pressure sensor variable by means of the pressure sensor.

### BACKGROUND INFORMATION

Typical pressure sensors have a diaphragm above a cavity for pressure detection, which diaphragm is deflected when pressure is applied. Both piezoelectric resistors and electrodes for realizing a capacitance are used as a measuring principle for detecting the deflection of the diaphragm.

German Patent Application No. DE 10 2009 001 924 A1 describes a pressure sensor with two pressure characteristics in which, after the central part of the diaphragm has been placed on the cavity base, the lateral regions can still be used for pressure detection.

German Patent Application No. DE 10 2021 207 745 A1, which is not a prior publication, describes a pressure sensor in which lateral stamps are provided that, in the case of capacitive pressure detection, shorten the distance from the electrode when the diaphragm is deflected.

### SUMMARY

The present invention provides a special construction of a pressure sensor that provides higher sensitivity in a second pressure range.

The present invention provides a micromechanical pressure sensor that derives a pressure sensor variable or a pressure sensor value from the deflection of a diaphragm by means of a capacitive measuring principle. For this purpose, a capacitor consisting of two electrodes is used, in which the distance between the two electrodes is reduced by an applied pressure. Furthermore, the present invention provides a corresponding method for producing said pressure sensor, in particular with micromechanical method steps. In addition, a method for operating the micromechanical pressure sensor or for detecting and deriving the pressure sensor variable as a function of a pressure applied to the diaphragm of the pressure sensor is also provided.

The pressure sensor according to an example embodiment of the present invention has a diaphragm that stretches over a cavity. A first electrode is provided in or on the diaphragm in a central region. A second electrode is provided on the cavity base so as to lie opposite the central region of the diaphragm or the first electrode. While the second electrode is arranged in a fixed and rigid manner, the first electrode in or on the diaphragm is designed so as to be able to be flexibly deflected together with the diaphragm and move toward the second electrode when a pressure is applied to the diaphragm. Together, the first and second diaphragm form a first measuring capacitor, by means of which a pressure can be detected up to a pressure threshold. When the pressure threshold is reached, the diaphragm is placed on the second electrode such that an additional pressure increase does not result in a further change in the capacitance. In order to allow even higher pressures to be detected, according to the present invention, a second measuring capacitor is provided in the lateral region of the diaphragm. The second measuring capacitor is formed by an additional first electrode in or on the lateral region of the diaphragm and a further second electrode which is arranged on the cavity base opposite the additional first electrode. It is important to the present invention that the distance between the electrodes of the second measuring capacitor is smaller than the distance between the electrodes of the first measuring capacitor.

An advantage of such a configuration is that two pressure ranges can be detected by means of the pressure sensor according to the present invention. Because the second pressure range above the pressure threshold has a smaller surface area for deflection on the diaphragm, significantly higher pressure values can be detected with this second measuring capacitor. By reducing the distance between the electrodes of the second measuring capacitor, the resolution and responsiveness to deflection can be increased.

According to an example embodiment of the present invention, in order to realize the smaller distance between the electrodes of the second measuring capacitor, it can be provided that the further second electrode is designed to be raised relative to the second electrode in the central region in relation to the cavity base. This can be achieved by making the electrode thicker or by arranging it on a pedestal.

Alternatively or additionally, an additional first electrode can be provided, which is arranged on the underside of the diaphragm in the lateral region. In this case, the additional first electrode can be attached directly to the diaphragm or can be arranged at a distance from the diaphragm in the direction of the cavity base or the further second electrode by means of a holding element.

Advantageously, according to an example embodiment of the present invention, a reference electrode can additionally be provided, which is assigned to at least one of the further rigid second electrodes. Thus, the reference electrode can be attached to the cavity base or produced in the underlying substrate, whereas the further second electrode is arranged or produced thereabove at a distance from the reference electrode.

Further advantages can be seen from the following description of exemplary embodiments of the present invention.

### BRIEF DESCRIPTION OF THE DRAWINGS

FIG. 1 schematically shows the mode of operation of a conventional capacitive pressure sensor.

FIG. 2 shows a first exemplary embodiment of the present invention.

FIG. 3 shows a second exemplary embodiment of the present invention.

FIG. 4 shows a combination of the configurations of both exemplary embodiments of the present invention.

### DETAILED DESCRIPTION OF EXAMPLE EMBODIMENTS

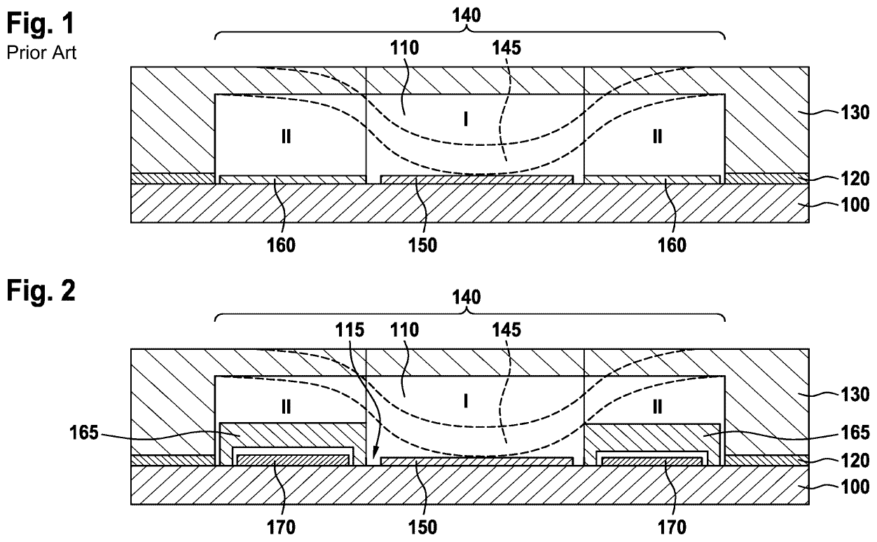

In a pressure sensor with a capacitive measuring principle, as shown in FIG. 1, a frame 130 having a diaphragm 140 is usually applied to a substrate 100 by means of a connecting layer 120. The frame 130 forms a cavity 110 with the substrate 100, which cavity preferably substantially has a vacuum. When pressure is applied from the outside, the diaphragm 140 is deflected, in extreme cases until it rests in a diaphragm state 145 in a central region I on the base of the cavity 110, an electrode 150 located there, or the substrate 100. In this case, it is provided in particular that the diaphragm 140 is designed with an insulating layer on the inside facing the cavity 110 in order to prevent a short circuit when being placed. Alternatively or additionally, the central electrode 150 can have an insulating layer. In order to detect the deflection of the diaphragm 140, in the case of a capacitive measuring principle, the diaphragm 140 is at least partially designed as a first flexible electrode having a first measuring capacitance. In addition, a second rigid electrode 150 of the first measuring capacitance is provided in particular at the base 115 of the cavity 100 on or in the substrate 100 opposite the diaphragm 140 and/or the first electrode. If the distance between the first and second electrode decreases due to the deflection of the diaphragm 140, a corresponding change in the detected capacitance can be detected as a measure of the applied pressure.

In a possible configuration of the capacitive pressure sensor, further pressure detection can also take place after the diaphragm 145 has been placed on the cavity base 115 or the lower second electrode 150 at a limit pressure value. This is made possible by the fact that at pressures higher than the limit pressure value, the lateral regions II of the diaphragm 140 or 145 can be deflected further, whereby they also come closer to the cavity base 115. In order to be able to detect this change in distance in the lateral region II of the diaphragm 140 above the limit pressure, it is necessary that the diaphragm 140 or 145 is also designed as a first electrode in this region and that further second rigid or fixed electrodes 160 are arranged on the cavity base 115 in the lateral region II. This additional second measuring capacitor in the lateral region II makes it possible to realize a second pressure range that is separate from the first pressure range. Because the diaphragm 140 in the lateral region II has a changed deflection behavior due to its stiffer design, this second pressure range can be recognized in the detected capacitance signal of the sensor by a pressure behavior that is different from the first pressure range. In the configuration of the further second electrodes 160, it can be provided that they are electrically connected to or electrically isolated from the central second electrode 150. This depends on the selected evaluation method, the respective possibilities of the evaluation circuit and the relevant application case. It may be desirable to represent both pressure ranges by means of a characteristic curve. In this case, the electrodes 150 and 160 are electrically connected to each other. In another case, it may be desirable to be able to switch between both characteristic curves at any time. In this other case, the electrodes 150 and 160 are electrically isolated from each other.

Because the distance between the diaphragm 140 in the lateral region II and the further second electrode 160 changes only slightly at a higher pressure applied to the diaphragm 140 above the limit pressure, it can be provided to bring the further electrode 165 closer to the first electrode in the diaphragm 140. Accordingly, FIG. 2 shows a first exemplary embodiment of the present invention, in which the further second electrode 165, which is arranged laterally relative to the central second electrode 150, is designed to be raised. Optionally, a reference electrode 170 can be arranged below the further second electrode 165, which, together with the rigid or fixedly installed further second electrode 165 located thereabove, results in a reference capacitor. This can be used to implement the Wheatstone bridge circuit, a measuring principle commonly used for pressure sensors.

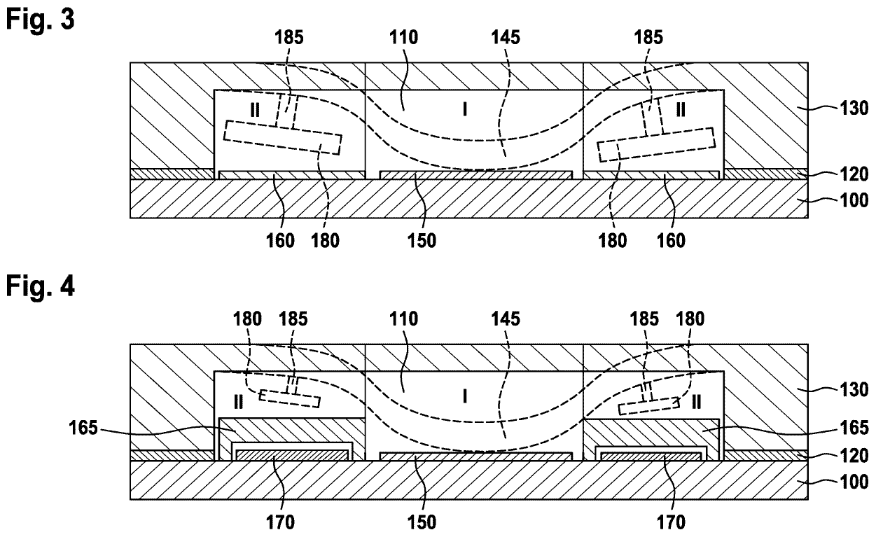

In a second exemplary embodiment, which is shown in FIG. 3, the distance between the electrodes of the lateral second measuring capacitor can also be reduced by providing additional first electrodes 180 in the lateral region II, which are brought closer to the further second electrodes 160, which are attached to the cavity base 115, on stamp-like configurations or a holding element 185 on the diaphragm 140.

The configurations of the two exemplary embodiments above can also be combined, as shown in FIG. 4.

The diaphragm 140 can be designed as a single first electrode that interacts with the corresponding second electrodes as measuring capacitors both in the central region I and in the lateral regions II. Optionally, it can be provided to connect the central second electrode in parallel with the further second electrodes 160 and 165. This would create a common measuring capacitance that is substantially determined by the central electrodes in the central region I in a first pressure range until the limit pressure value is reached (=placement of the diaphragm 145 on the cavity base 115 or on the first central electrode) and by the lateral electrodes above the limit pressure value.

Alternatively, however, it can also be provided that the diaphragm 140 has a central first electrode and an additional first electrode in the lateral region II. Furthermore, it can be provided that the second central electrode 150 and the laterally arranged further second electrodes 160 and 165 are electrically isolated from one another and can also be read out separately. This makes it possible to realize, in addition to the central first measuring capacitor, a second laterally arranged measuring capacitor, which is read out separately only for the second pressure range. The measures described in this patent allow this capacitor to be optimized specifically for the second pressure range with a sufficiently high sensitivity.

Optionally, it can be provided that the additional first electrode in the diaphragm 140 and the further second electrode 160 or 165 are provided only in one lateral region of the cavity.

1-6. (canceled)

7. A micromechanical capacitive pressure sensor, comprising:
a diaphragm that stretches over a cavity;
a flexible first electrode assigned to a central region of the diaphragm;
a rigid second electrode opposite the central region on a cavity base of the cavity;
a flexible additional first electrode assigned to a lateral region of the diaphragm; and
a rigid further second electrode opposite the lateral region on the cavity base;
wherein a distance between the additional first electrode and the further second electrode in the lateral region is smaller than a distance between the first electrode and the second electrode in the central region.

8. The micromechanical capacitive pressure sensor according to claim 7, wherein the at least one further second electrode is arranged at least partially further away from the cavity base than the second electrode.

9. The micromechanical capacitive pressure sensor according to claim 7, wherein the at least one additional first electrode is arranged at a distance from an underside of the diaphragm using a holding element.

10. The micromechanical capacitive pressure sensor according to claim 7, wherein the at least one further second electrode is assigned a reference electrode, the reference electrode being arranged on the cavity base and the further second electrode being is arranged at a distance above the reference electrode.

11. A method for producing a micromechanical capacitive pressure sensor, the method comprising the following steps:
producing, using micromechanical methods, the micromechanical capactive pressure sensor including:
a diaphragm that stretches over a cavity,
an assigned flexible first electrode in or on a central region of the diaphragm,
a rigid second electrode opposite the central region on a cavity base of the cavity,
a flexible additional first electrode assigned to a lateral region of the diaphragm, and
a rigid further second electrode opposite the lateral region of the diaphragm on the cavity base;
wherein during the production, a smaller distance is provided between the additional first electrode and the further second electrode in the lateral region than a distance between the first electrode and the second electrode in the central region.

12. A method for detecting a pressure sensor signal with a micromechanical capacitive pressure sensor, the pressure sensor including:
a diaphragm that stretches over a cavity,
a flexible first electrode assigned to a central region of the diaphragm,
a rigid second electrode opposite the central region on a cavity base of the cavity,
a flexible additional first electrode assigned to a lateral region of the diaphragm; and
a rigid further second electrode opposite the lateral region on the cavity base,
wherein a distance between the additional first electrode and the further second electrode in the lateral region is smaller than a distance between the first electrode and
the second electrode in the central region,
the method comprising the following steps:
in a first pressure range up to a pressure threshold, deriving a pressure variable by detecting a capacitance between the first electrode and the second electrode in the central region of the diaphragm; and
in a second pressure range above the pressure threshold, deriving the pressure variable by detecting ae capacitance between the additional first electrode and the further second electrode in the lateral region of the diaphragm.
